(19) United States
(12) Patent Application Publication
(10) Pub. No.: US 2003/0109130 A1
(43) Pub. Date: Jun. 12, 2003

(54) Dual-gate process with CMP

(75) Inventor: Hsiang-Jen Huang, Mohegan Lake, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY

(21) Appl. No.: 10/010,258

(22) Filed: Dec. 7, 2001

(51) Int. Cl. H01L 21/4763

(52) U.S. Cl. 438/633

(57) ABSTRACT

In a dual-gate MOSFET process, the first gate oxide is covered by a protective layer of poly that will become the transistor gate while the second gate oxide thickness is formed and, in turn, covered by a second protective layer of poly that will become the second transistor gate, the two protective layers being patterned simultaneously to form first and second sets of gates having first and second gate dielectric thicknesses, respectively.

### FIELD OF THE INVENTION

The field of the invention is MOSFET integrated circuit processing, in particular circuits having two gate thicknesses (dual-gate).

### BACKGROUND OF THE INVENTION

In a conventional dual-gate process, the first gate oxide is covered directly with photoresist, which often contains contaminants such as Na. Such contaminants can increase the conductivity of the film and/or change the transistor threshold voltage.

In addition, the second oxide is sensitive to the cleaning step. If a thorough clean is performed, the cleaning process may damage the first oxide. If the cleaning is not thorough, then the quality of the second oxide suffers.

### SUMMARY OF THE INVENTION

The invention relates to a process for forming two MOSFET gate oxide thicknesses, in which protective poly layers cover the gate oxides for both types of transistor, thereby protecting against contamination and against damage from cleaning.

A feature of the invention is the use of an oversized protective layer, so that undercutting of the gate oxide during intermediate steps does not affect the active area.

Another feature of the invention is the use of chemical-mechanical polishing (CMP) to establish a flat surface for the gate litho step.

Yet another feature of the invention is the simultaneous definition of both types of gate.

### BRIEF DESCRIPTION OF THE DRAWINGS

FIGS. 1 through 4 show in cross section a portion of an integrated circuit that will contain one gate of each of two types.

### DESCRIPTION OF THE PREFERRED EMBODIMENT

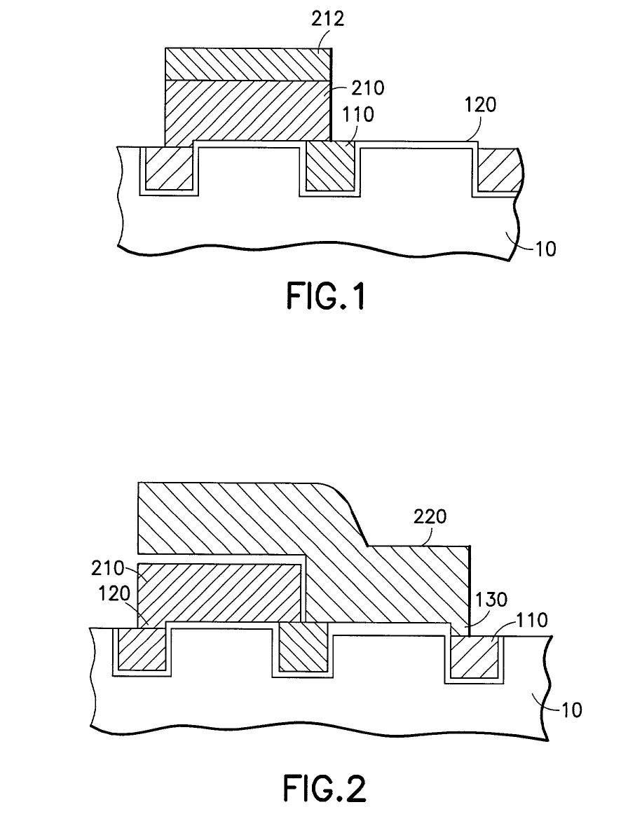

FIG. 1 shows in cross section a portion of an integrated circuit that will contain two transistors, one having a thinner oxide and the other having a thicker oxide.

Conventional shallow trench isolation members (STI) 110 formed in substrate 10 divide the figure into two sections. For convenience in the claims, preliminary steps such as blanket implants, threshold implants, etching the STI will be referred to as “preparing the substrate”. On the left a thin gate oxide, illustratively about 1.5 nm thick, has been grown. A blanket poly layer, illustratively about 150 nm thick (appropriate for a gate electrode), has been put down, covered with photoresist 212 and patterned to form a first cover member 210 that protects gate oxide 120 over the active areas of the thin-gate transistors. It should be noted that member 210 is oversized with respect to the transistor active area, extending over the STI on each side. This provides the beneficial feature that undercutting during wet etch steps will not affect the gate oxide over the active area, because the trimming to fit the active area will remove any potentially damaged areas.

Next, in FIG. 2, the same area is shown after a second (thicker) gate oxide 130, illustratively about 4 nm thick, has been grown, covered with a second poly blanket layer that has been patterned to define second protective member 220, illustratively about 180 nm thick (and also appropriate for a gate electrode). Note that patterning member 220 is a non-critical litho step because it stops over STI on both sides. For example, if member 220 is cut off too far to the left, so that there is a sidewall at the left edge of member 210, that would not make any difference because the subsequent trimming of member 210 will remove any possible sidewall. Note that thick oxide 130 extends over the top of poly member 210, providing a useful marker for the top of member 210.

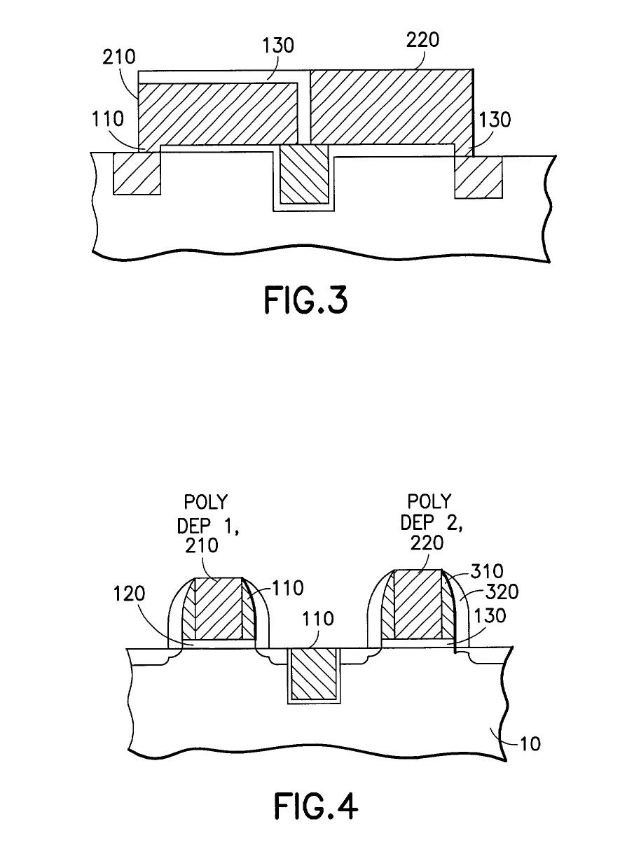

Referring now to FIG. 3, there is shown the results of a chemical-mechanical polishing (CMP) operation, stopping on thick oxide 130. There is a coplanar surface—the top of member 220 is coplanar with the top of oxide 130 on member 210. The purpose of this step is to present a planar surface for the subsequent step of patterning the gates of both transistors simultaneously. If the CMP step were not done, the pattern for one or both types of gate would be out of focus. Dimensions and tolerances are so tight in current advanced litho practice that such a step difference would not be tolerable.

Another purpose of this approach is also to avoid having the gate dielectric layer exposed to photoresist during gate dielectric definition. The use of CMP to remove the portion of layer 220 resting on layer 210 eliminates the need for a dry etch process stopping on oxide 130 for defining the second polysilicon layer. This can avoid some concerns of leaving residual poly after the dry etch process, such as poly sidewalls on the side of the first poly layer 210.

In a preliminary step, the remainder of oxide 130 on the top of member 210 can be removed at any convenient time, e.g. by wet etching.

Referring now to FIG. 4, the same area is shown after a number of conventional steps. Protective members 210 and 220 have both been patterned in the same litho step, in which an aperture has been formed (stopping on silicon 10) about STI members 110 that is sufficiently large to hold the sidewalls and source/drain implants. Conventional sidewalls oxide 310, and nitride 320 have been formed following the standard procedure, together with the associated implants to form the low-doped drain and source/drain contact regions, respectively.

After the steps in FIG. 4, contacts, interconnects, and other conventional back end steps will be performed, referred to for convenience in the claims, as “completing the circuit”.

Those skilled in the art will recognize that first gate oxide 120 is preferably stripped to remove any possible contamination from the etching process that patterned member 210, but that this is not essential. Second gate dielectric 130 could be a conventional oxide or an oxynitride for better performance as an etch stop. Preferably the first gate dielectric is the thinner of the two, but this is not essential.

The invention can be used with both bulk and SOI substrates and with CMOS as well as single-polarity circuits.

While the invention has been described in terms of a single preferred embodiment, those skilled in the art will recognize that the invention can be practiced in various versions within the spirit and scope of the following claims.

We claim:

1. A method of forming a dual-gate integrated circuit comprising the steps of:
preparing a substrate;
forming and filling with dielectric a set of shallow isolation trenches defining a set of active areas;
forming a first gate dielectric layer, having a first gate dielectric layer thickness, on a top surface of said substrate;
depositing a first protective polysilicon layer and patterning said first protective polysilicon layer to cover a first subset of active areas;
forming a second gate dielectric layer, having a second gate dielectric layer thickness, over a second subset of active areas and over said first protective layer;
depositing a second protective polysilicon layer over said second subset of active areas and over said first protective layer, whereby said first and second protective layers are separated by said second gate dielectric layer over said first subset of active areas;
chemical-mechanical polishing said second protective layer using said second gate dielectric as a polish stop, thereby establishing a top surface over said first and second protective layers;
patterning said first and second protective layers to form a set of first and second transistor gates within said first and second subsets of active areas;
completing transistors using both said set of first and second transistor gates and having said first and second gate dielectric layer thicknesses; and
completing said circuit.

2. A method according to claim 1, in which both of said first and second protective layers are patterned to cover corresponding active area subsets and to extend over said shallow trench isolation trenches.

3. A method according to claim 1, in which said first gate dielectric layer is stripped outside of said first protective polysilicon layer covering said first subset of active areas before said second gate dielectric layer is formed.

4. A method according to claim 2, in which said first gate dielectric layer is stripped outside of said first protective polysilicon layer covering said first subset of active areas before said second gate dielectric layer is formed.

5. A method according to claim 1, in which said step of patterning said first and second protective layers to form a set of first and second transistor gates is performed simultaneously on said first and second protective layers.

6. A method according to claim 2, in which said step of patterning said first and second protective layers to form a set of first and second transistor gates is performed simultaneously on said first and second protective layers.

7. A method according to claim 3, in which said step of patterning said first and second protective layers to form a set of first and second transistor gates is performed simultaneously on said first and second protective layers.

8. A method according to claim 4, in which said step of patterning said first and second protective layers to form a set of first and second transistor gates is performed simultaneously on said first and second protective layers.

9. A method according to claim 2, in which both of said first and second gate dielectric layers are formed of thermal oxide.

10. A method according to claim 2, in which said second gate dielectric layer is formed of oxynitride.
